(19) United States
(12) Patent Application Publication
(10) Pub. No.: US 2026/0247560 A1
(43) Pub. Date: Aug. 20, 2026

(54) SERVER MOUNTING SYSTEM

(71) Applicant: Quanta Computer Inc., Taoyuan City (TW)

(72) Inventors: Yaw-Tzorng TSORNG, Taoyuan City (TW); Ming-Lung WANG, Taoyuan City (TW); Wei-Kang TSAI, Taoyuan City (TW); Pei-Jung HSIEH, Taoyuan City (TW)

(21) Appl. No.: 19/055,885

(22) Filed: Feb. 18, 2025

(51) Int. Cl. H05K 7/14

(52) U.S. Cl. CPC H05K 7/1489

(57) ABSTRACT

A server mounting system includes a mounting post, a server chassis, and a mounting accessory. The mounting post includes a mounting rail containing a plurality of mounting holes. The server chassis includes a side panel with an outside surface, an inside surface, and at least one elongated mounting slot disposed through the side panel between the outside surface and the inside surface. The mounting accessory is defined in part by a plate, and is configured to couple the server chassis to the mounting post. The mounting accessory includes a lock component extending from the mounting accessory and configured to securely couple with the elongated mounting slot. The mounting accessory also includes a captive screw disposed through the plate. The captive screw is free to rotate relative to the plate, and is configured to threadably mate with one of the plurality of mounting holes.

### FIELD OF THE INVENTION

The present invention relates generally to a mounting accessory for installing a server chassis in a server cabinet. More specifically, the mounting accessory is intuitively assembled to the server chassis without tools, and adjustable to match the installation depth of the server chassis to the server cabinet.

### BACKGROUND OF THE INVENTION

Edge servers as commonly used in the 5G telecommunication market are installed in server cabinets of different specifications, sizes, and depths. However, existing server products on the market are designed with server chassis having fixed-position mounting accessories. The installation depth of such a server chassis within a server cabinet is therefore limited by the fixed-position mounting accessories. There is also a chance that the fixed-position mounting accessories can be damaged during packaging or transportation, thus making them unusable for mounting.

A need exists for a server mounting system that allows the installation depth of the server chassis to be adjusted so that the depth of the server chassis can flexibly match the depth restrictions of various server cabinets. It would be beneficial if the server mounting system included separate intuitively installed mounting accessories to avoid any possibility of damage during packaging or transportation.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a server mounting system includes a mounting post, a server chassis, and a mounting accessory. The mounting post includes a mounting rail including a plurality of mounting holes. The server chassis includes a side panel with an outside surface, an inside surface, and at least one elongated mounting slot disposed through the side panel between the outside surface and the inside surface. The mounting accessory is defined in part by a plate, and is configured to couple the server chassis to the mounting post. The mounting accessory includes a lock component extending from the mounting accessory and configured to securely couple with the elongated mounting slot. The mounting accessory also incudes a captive screw disposed through the plate. The captive screw is free to rotate relative to the plate, and is configured to threadably mate with one of the plurality of mounting holes.

According to certain aspects of the present disclosure, the plate is a first plate, and the mounting accessory is further defined by a second plate. The second plate extends in a first direction transversely away from an edge of the first plate. The lock component extends from the second plate in a second direction away from the first plate. The captive screw is oriented such that threads of the captive screw extend in the first direction.

According to certain aspects of the present disclosure, the lock component includes a cap component having a cap diameter.

According to certain aspects of the present disclosure, the lock component further includes a hollow body affixed to the second plate, a spring, and a pin disposed through the hollow body. The pin includes a first flange at a first end and a second flange at a second end. The cap component is disposed around the pin and captured between the first flange and an outside of the hollow body. The spring is captured between the second flange and an inside of the hollow body. The spring biases the first flange toward the hollow body.

According to certain aspects of the present disclosure, the elongated mounting slot has a first end having a maximum opening that is larger than the cap diameter and a second end having a maximum opening that is smaller than the cap diameter.

According to certain aspects of the present disclosure, the elongated mounting slot is at least partly bounded by bridge elements extending away from the inside surface of the side panel. A bridge element extends along each long edge of the elongated mounting slot between the first end and the second end. Each bridge element has a first ramped surface facing the first end of the elongated mounting slot and a second ramped surface facing the second end of the elongated mounting slot.

According to certain aspects of the present disclosure, a side of the cap component facing the hollow body includes a ramped surface. The ramped surface of the cap component extends radially away from a circumferential edge of the cap component. The ramped surface of the cap component is configured to be complementary to the first and second ramped surfaces of each bridge element.

According to certain aspects of the present disclosure, the server mounting system further includes a supporting tab extending away from the outside surface of the side panel and spaced from a long edge of the elongated mounting slot.

According to certain aspects of the present disclosure, a server mounting system includes a mounting post, a server chassis, and a mounting accessory. The mounting post includes a mounting rail containing a plurality of mounting holes. The server chassis includes a side panel with an outside surface, an inside surface, and at least two elongated mounting slots disposed through the side panel between the outside surface and the inside surface. The mounting accessory is defined in part by a plate, and is configured to couple the server chassis to the mounting post. The mounting accessory is configured to couple the server chassis to the mounting post. The mounting accessory incudes a first plate, a second plate, a lock component, and a captive screw. The second plate extends in a first direction transversely away from an edge of the first plate. The lock component extends from the second plate in a second direction away from the first plate. The lock component is configured to securely couple with one of the elongated mounting slots. The captive screw is disposed through the first plate. The captive screw is free to rotate relative to the first plate and is oriented such that threads of the captive screw extend in the first direction. The captive screw is configured to threadably mate with one of the plurality of mounting holes.

According to certain aspects of the present disclosure, the lock component includes a cap component having a cap diameter, a hollow body affixed to the second plate, a spring, and a pin disposed through the hollow body. The pin includes a first flange at a first end and a second flange at a second end. The cap component is disposed around the pin and captured between the first flange and an outside of the hollow body. The spring is captured between the second flange and an inside of the hollow body The spring biases the first flange toward the hollow body.

According to certain aspects of the present disclosure, each of the elongated mounting slots has a first end having a maximum opening that is larger than the cap diameter and a second end having a maximum opening that is smaller than the cap diameter.

According to certain aspects of the present disclosure, each of the elongated mounting slots is at least partly bounded by bridge elements extending away from the inside surface of the side panel. A bridge element extends along each long edge of each elongated mounting slot between the first end and the second end. Each bridge element has a first ramped surface facing the first end of one of the elongated mounting slots and a second ramped surface facing the second end of the one of the elongated mounting slots.

According to certain aspects of the present disclosure, a side of the cap component facing the hollow body includes a ramped surface. The ramped surface of the cap component extends radially away from a circumferential edge of the cap component. The ramped surface of the cap component is configured to be complementary to the first and second ramped surfaces of each bridge element.

According to certain aspects of the present disclosure, a server mounting system includes a server chassis and two mounting accessories. The server chassis has two opposite side panels. Each side panel includes an outside surface and an inside surface. Each side panel includes at least two elongated mounting slots disposed through the side panel between the outside surface and the inside surface of the side panel. Each mounting accessory is configured to couple one of the two opposite side panels to a mounting post. Each mounting accessory is defined in part by a plate, and includes a lock component and a captive screw. The lock component extends from the mounting accessory and is configured to securely couple with one of the elongated mounting slots. The captive screw is disposed through the plate. The captive screw is free to rotate relative to the plate and is configured to mate with a threaded hole on a mounting rail of the mounting post.

According to certain aspects of the present disclosure, the plate is a first plate, and the mounting accessory is further defined by a second plate. The second plate extends in a first direction transversely away from an edge of the first plate. The lock component extends from the second plate in a second direction away from the first plate. The captive screw is disposed through the first plate and oriented such that threads of the captive screw extend in the first direction.

According to certain aspects of the present disclosure, the lock component includes a cap component having a cap diameter, a hollow body affixed to the second plate, a spring, and a pin disposed through the hollow body. The pin includes a first flange at a first end and a second flange at a second end. The cap component is disposed around the pin and captured between the first flange and an outside of the hollow body. The spring is captured between the second flange and an inside of the hollow body. The spring biases the first flange toward the hollow body.

According to certain aspects of the present disclosure, each of the elongated mounting slots has a first end having a maximum opening that is larger than the cap diameter and a second end having a maximum opening that is smaller than the cap diameter.

According to certain aspects of the present disclosure, each of the elongated mounting slots is at least partly bounded by bridge elements extending away from the inside surface of the side panel. A bridge element extends along each long edge of each elongated mounting slot between the first end and the second end. Each bridge element has a first ramped surface facing the first end of one of the elongated mounting slots and a second ramped surface facing the second end of the one of the elongated mounting slots.

According to certain aspects of the present disclosure, the server mounting system further includes a plurality of supporting tabs. Each supporting tab extends away from the outside surface of one of the two opposite side panels, and is spaced from a long edge of one of the elongated mounting slots. A side of the cap component facing the hollow body includes a ramped surface extending radially away from a circumferential edge of the cap component. The ramped surface is configured to be complementary to the first and second ramped surfaces of the bridge element.

According to certain aspects of the present disclosure, a method of securing a server within a server cabinet having two mounting posts using the server mounting system described above is presented for each of the two opposite side panels of the server chassis. The method includes aligning the lock component of one of the two mounting accessories with the maximum opening of the first end of one of the elongated mounting slots. The method further includes inserting the lock component of the one of the two mounting accessories into the first end of the one of the elongated mounting slots until the second plate of the one of the two mounting accessories is in contact with a supporting tab. The method further includes applying force to the one of the two mounting accessories in a direction toward the second end of the one of the elongated mounting slots, such that the ramped surface of the cap component is engaged by the first ramped surface of each bridge element. The method further includes continuing to apply force to the one of the two mounting accessories in the direction toward the second end of the one of the elongated mounting slots, such that engagement of the ramped surface of the cap component by the first ramped surface of each bridge element forces the cap component away from the hollow body against a bias of the spring. The method further includes continuing to apply force to the one of the two mounting accessories in the direction toward the second end of the one of the elongated mounting slots, such that the bias of the spring maintains engagement of the ramped surface of the cap component with the second ramped surface of each bridge element until the cap component makes contact with the inside surface of the server chassis. The method further includes screwing the threads of the captive screw of the one of the two mounting accessories securely into the threaded hole on the mounting rail of one of the two mounting posts.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective schematic view showing a server chassis mounted in a server cabinet by an exemplary server mounting system, according to certain aspects of the present disclosure.

FIG. 2 is a perspective schematic view showing an exemplary mounting accessory, according to certain aspects of the present disclosure.

FIG. 3 is a perspective schematic view of an exemplary lock component of a mounting accessory, according to certain aspects of the present disclosure.

FIG. 4 is a cross-sectional view taken generally along the lines 4-4 of the exemplary lock component of FIG. 3, according to certain aspects of the present disclosure.

FIG. 5 is a perspective schematic view of a mounting accessory being aligned with an elongated mounting slot prior to insertion into the elongated mounting slot, according to certain aspects of the present disclosure.

FIG. 6 is a side elevational view of a mounting accessory inserted into a first end of an elongated mounting slot, according to certain aspects of the present disclosure.

FIG. 7 is a top plan view of the mounting accessory inserted into the first end of the elongated mounting slot shown in FIGS. 5 and 6, according to certain aspects of the present disclosure.

FIG. 8 is a perspective schematic view of the mounting accessory inserted into the first end of an elongated mounting slot shown in FIG. 6, according to certain aspects of the present disclosure.

FIG. 9 is a schematic perspective view of the mounting accessory in an intermediate position within the elongated mounting slot during installation of the mounting accessory within the elongated mounting slot, according to certain aspects of the present disclosure.

FIG. 10 is a side elevational view of the mounting accessory in an intermediate position within the elongated mounting slot shown in FIG. 9, according to certain aspects of the present disclosure.

FIG. 11 is a top plan view of the mounting accessory in an intermediate position within the elongated mounting slot shown in FIGS. 9 and 10, according to certain aspects of the present disclosure.

FIG. 12 is a cross-sectional view taken generally along the lines 12-12 of FIG. 10 showing the geometric relationship of the lock component and the bridge elements in the intermediate position, according to certain aspects of the present disclosure.

FIG. 13 is a schematic perspective view of the mounting accessory in an intermediate position within the elongated mounting slot during installation of the mounting accessory within the elongated mounting slot for reference and comparison with FIG. 14, according to certain aspects of the present disclosure.

FIG. 14 is a schematic perspective view of the mounting accessory in an installed position within the elongated mounting slot, according to certain aspects of the present disclosure.

FIG. 15 is a side elevational view of the mounting accessory in the installed position within the elongated mounting slot as shown in FIG. 14, according to certain aspects of the present disclosure.

FIG. 16 is a top plan view of the mounting accessory in the installed position within the elongated mounting slot as shown in FIGS. 14 and 15, according to certain aspects of the present disclosure.

FIG. 17 is a cross-sectional view taken generally along the lines 17-17 of FIG. 15 showing the geometric relationship of the lock component and the bridge elements in the installed position, according to certain aspects of the present disclosure.

FIG. 18 is a flow diagram for the steps of a method of securing a server chassis within a server cabinet for each of two opposite side panels of the server chassis, according to certain aspects of the present disclosure.

FIG. 19 is a perspective schematic view showing the server chassis of FIG. 1 mounted at a different depth within the server cabinet of FIG. 1 by the exemplary server mounting system, according to certain aspects of the present disclosure.

### DETAILED DESCRIPTION

The current invention is a system for mounting a server chassis within a server cabinet The mounting system uses an intuitive spring-loaded lock mechanism on a mounting accessory that pushes into place for ease of installation without tools. The mounting system is efficient and labor-saving for quick assembly and disassembly. The mounting system has a simple and modular structure that can be used on various server chassis and server cabinets.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

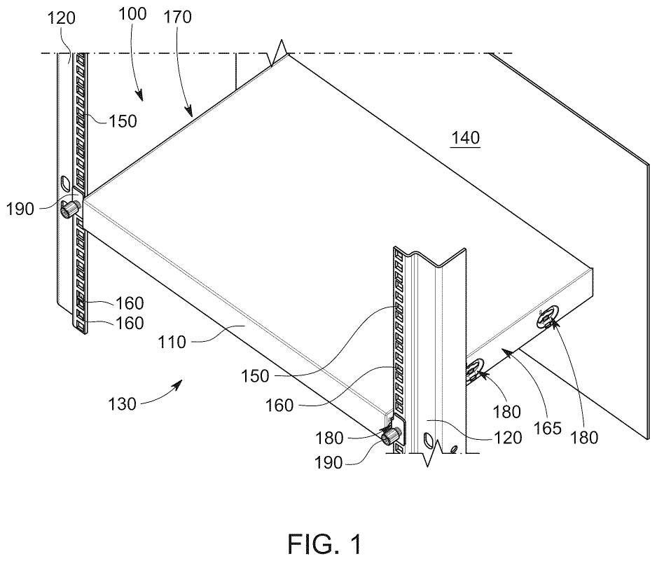

Referring to FIG. 1, a server mounting system 100 is shown for mounting a server chassis 110 to mounting posts 120 of a server cabinet 130 that includes at least the mounting posts 120 and a cabinet rear wall 140. In an embodiment, the server cabinet includes two mounting posts 120, each mounting post 120 including a mounting rail 150. Each of the mounting rails 150 includes a plurality of mounting holes 160. Some or all of the plurality of mounting holes 160 are threaded.

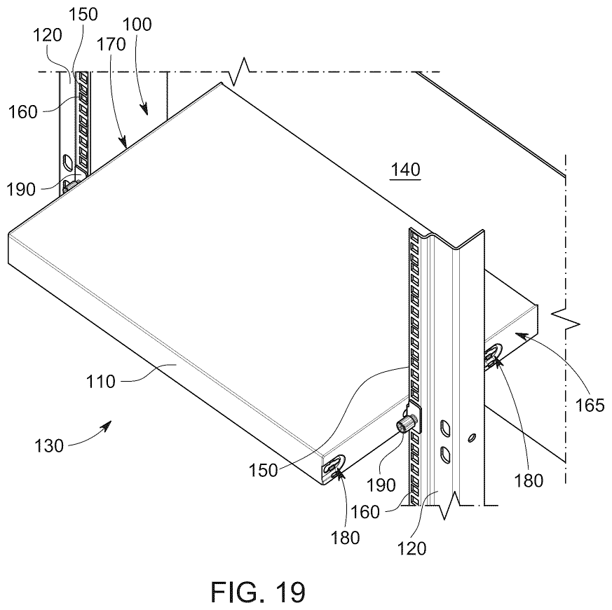

The server chassis 110 includes first side panel 165 and second side panel 170. In an embodiment, at least one elongated mounting slot 180 is disposed through each of the first and second side panels 165, 170. For example, three elongated mounting slots 180 are shown in FIG. 1. In other embodiments, there can be one, two, four, or more elongated mounting slots 180 disposed through each of the first and second side panels 165, 170. Having a plurality of elongated mounting slots 180 allows for the server chassis 110 to be mounted at different depths within the server cabinet 130 (see FIG. 19). A mounting accessory 190 is configured to couple the server chassis 110 to each mounting post 120.

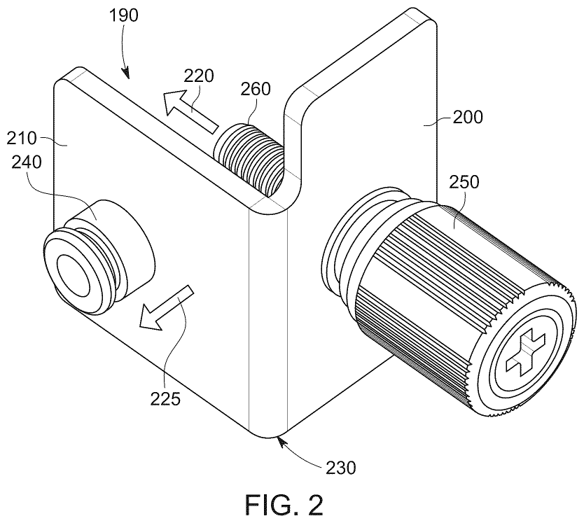

Referring to FIG. 2, the mounting accessory 190 is configured to couple the server chassis 110 to each mounting post 120. The mounting accessory 190 includes a first plate 200 and a second plate 210 extending in a first direction 220 transversely away from an edge 230 of the first plate 200. The mounting accessory 190 also includes a lock component 240 extending from the mounting accessory 190 and configured to securely couple with one of the elongated mounting slots 180. The lock component 240 extends from the second plate 210 in a second direction 225 away from the first plate 200. A captive screw 250 is disposed through and free to rotate relative to the first plate 200. The captive screw 250 is oriented through the first plate 200 such that threads 260 of the captive screw 250 extend in the first direction 220. The threads 260 are configured to threadably mate with one of the plurality of mounting holes 160 disposed through the mounting rail 150 of one of the mounting posts 120.

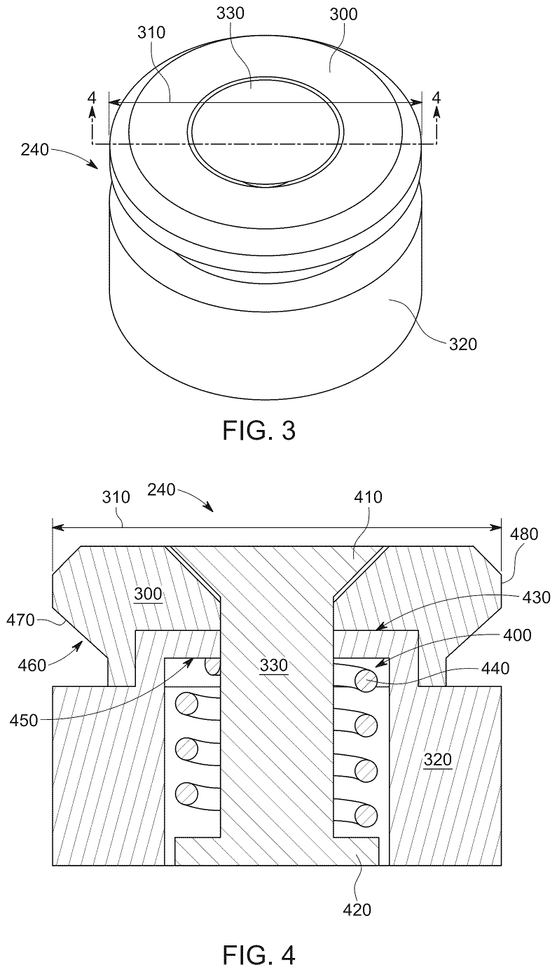

Referring to FIG. 3, the lock component 240 includes a cap component 300 having a maximum cap cross-sectional dimension 310. The cap component 300 illustrated in FIG. 3 is round such that its maximum cap cross-sectional dimension 310 is a diameter of the cap component 300. In other embodiments, the cap component 300 can be other than round but still has the maximum cap cross-sectional dimension 310. The lock component 240 includes a hollow body 320 that is affixed to the second plate 210. Also externally visible in FIG. 3, an end of pin 330 is disposed through the hollow body 320.

Referring to FIG. 4, the lock component 240 is shown in a cross-sectional view taken generally along the lines 4-4 of FIG. 3. The hollow body 320 includes an interior space 400. The pin 330 is disposed through the hollow body 320. The pin 330 includes a first flange 410 at a first end and a second flange 420 at a second end. The cap component 300 is disposed around the pin 330 and captured between the first flange 410 and an outside surface 430 of the hollow body 320. A spring 440 is captured within the interior space 400 between the second flange 420 and an inside surface 450 of the hollow body 320. The spring 440 biases the first flange 410 toward the hollow body 320. A side 460 of the cap component 300 facing the hollow body 320 includes a first ramped surface 470 extending radially away from a circumferential edge 480 of the cap component 300.

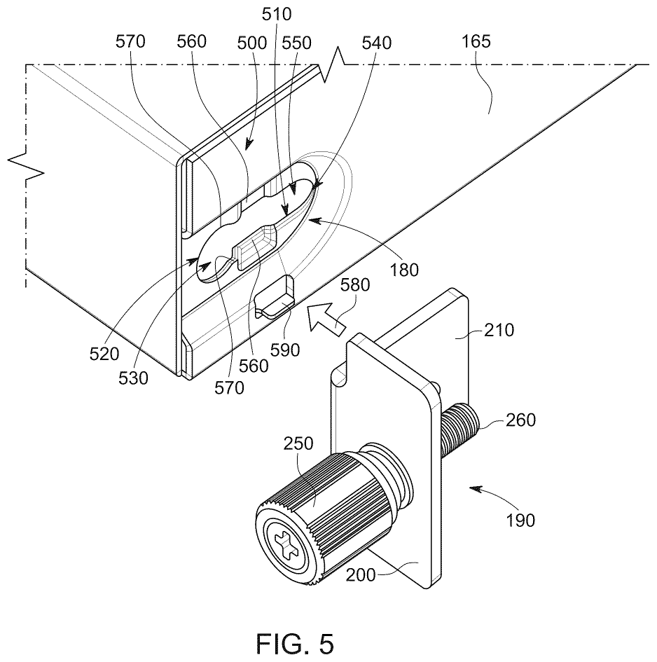

Referring to FIG. 5, each of the first and second side panels 165, 170 includes an outside surface 500 and an inside surface 510. Each elongated mounting slot 180 is disposed through one of the first or second side panels 165, 170 between the outside surface 500 and the inside surface 510. Each elongated mounting slot 180 has a first end 520 having a maximum opening 530 that is larger than the maximum cap cross-sectional dimension 310, and a second end 540 having a maximum opening 550 that is smaller than the maximum cap cross-sectional dimension 310.

Each elongated mounting slot 180 is at least partly bounded by a bridge element 560 extending away from the inside surface 510 of the first or the second side panel 165, 170 along each long edge 570 of the elongated mounting slot 180 between the first end 520 and the second end 540. The lock component 240 of the mounting accessory 190 is initially accommodated by the maximum opening 530 when the mounting accessory 190 is moved toward the elongated mounting slot 180, as indicated by the arrow 580. A supporting tab 590 extends away from the outside surface 500 of each of the first and second side panels 165, 170. The supporting tab 590 is spaced from a long edge 570 of a corresponding closest elongated mounting slot 180.

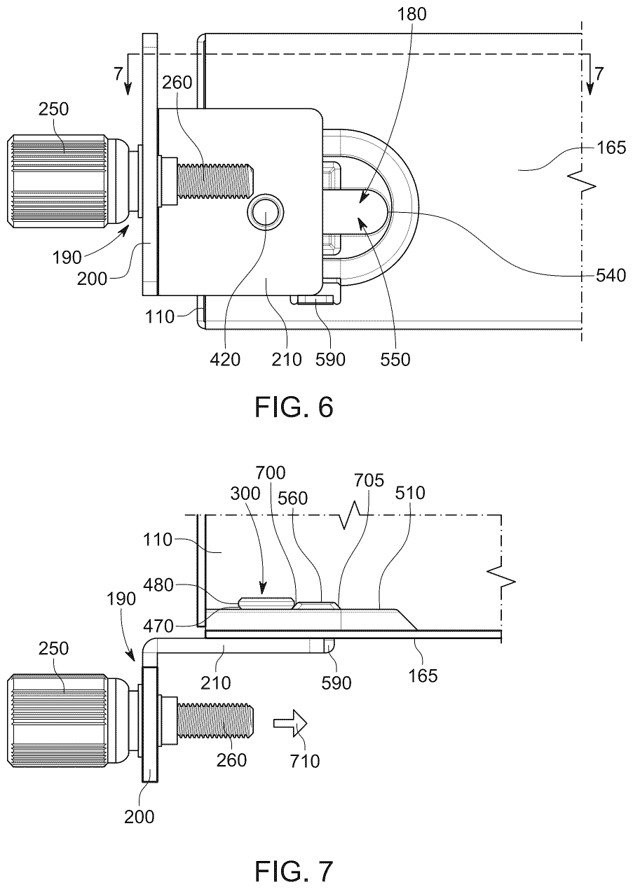

Referring to FIG. 6, the mounting accessory 190 is shown in a side elevation with the lock component 240 (not visible) inserted into the maximum opening 530 of the elongated mounting slot 180 and the second plate 210 in contact with the supporting tab 590. As further described below, this insertion is a step in attaching the mounting accessory 190 to the server chassis 110.

Now also referring to FIG. 7, which is a top plan view looking generally along the lines 7-7 of FIG. 6, the cap component 300 is visible on an inside of the server chassis 110. The bridge element 560 has a second ramped surface 700 facing the first end 520 of the elongated mounting slot 180 and a third ramped surface 705 facing the second end 540 of the elongated mounting slot 180. The first ramped surface 470 of the cap component 300 is configured to be complementary to the second and third ramped surfaces 700, 705 of the bridge element 560.

FIGS. 6 and 7 further illustrate the mounting accessory 190 after being inserted into the elongated mounting slot 180 and being pushed by an application of force in a direction shown by arrow 710 toward the second end 540 of the elongated mounting slot 180. In this configuration, the first ramped surface 470 of the cap component 300 is engaged by the second ramped surface 700 of each bridge element 560 facing the first end 520 of the elongated mounting slot 180.

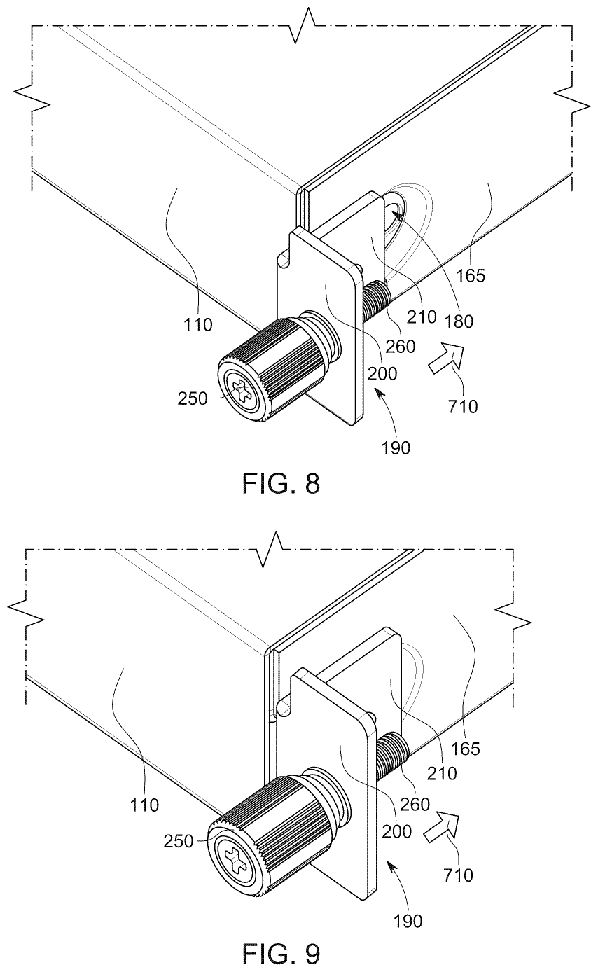

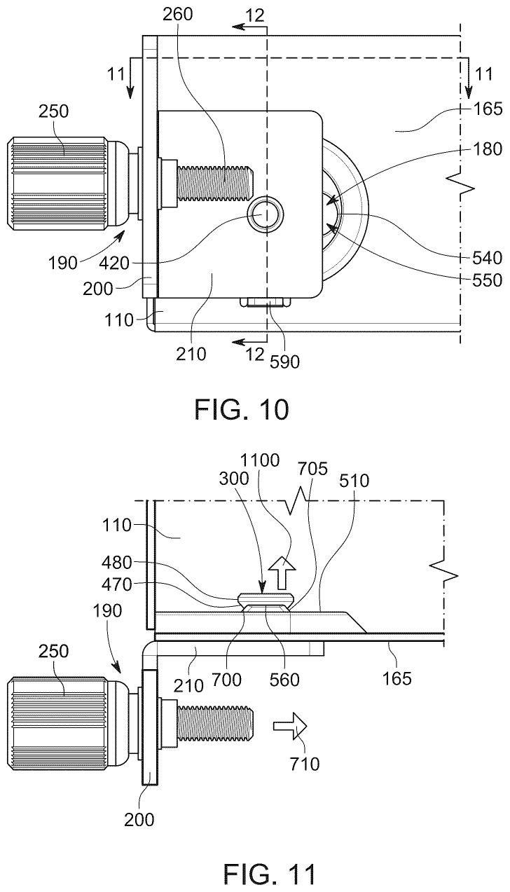

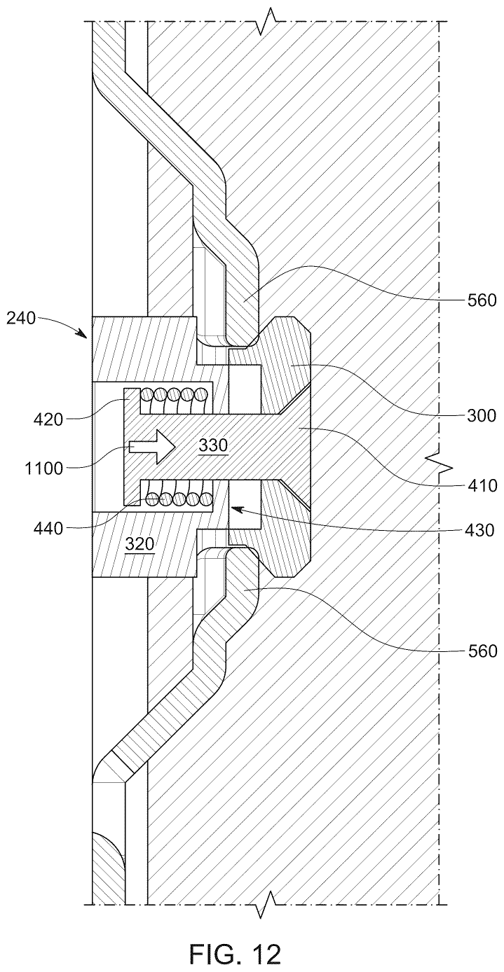

Referring to FIG. 8, the mounting accessory 190 is shown in an external perspective view in the same position relative to the server chassis 110, as it is shown in FIGS. 6 and 7. Continuing to apply force to the mounting accessory 190 in the direction of arrow 710 after the engagement of the first and second ramped surfaces 470, 700, as shown in FIG. 7, forces the cap component 300 to move up the second ramped surfaces 700. The cap component 300 also moves away from the hollow body 320 against a bias of the spring 440 until the mounting accessory 190 reaches the position relative to the server chassis 110 as shown in FIGS. 9 and 10. FIGS. 11 and 12 are additional views of the mounting accessory 190 in the position shown in FIGS. 9 and 10, and show additional geometric details of the interaction of the cap component 300 with the bridge elements 560.

Looking generally along the lines 11-11 of FIG. 10, FIG. 11 shows the cap component 300 pushed away from the inside surface 510 in the direction of the arrow 1100 by the bridge elements 560. Looking generally along the lines 12-12 of FIG. 10, FIG. 12 also shows the cap component 300 separated from the outside surface 430 of the hollow body 320. The pin 330 has been pulled by the cap component 300 in the direction of arrow 1100, thereby compressing the spring 440. In this configuration, the cap component 300 is supported by the bridge elements 560 against the bias of the spring 440 that has been compressed relative to the rest position of the spring 440 shown in FIG. 4.

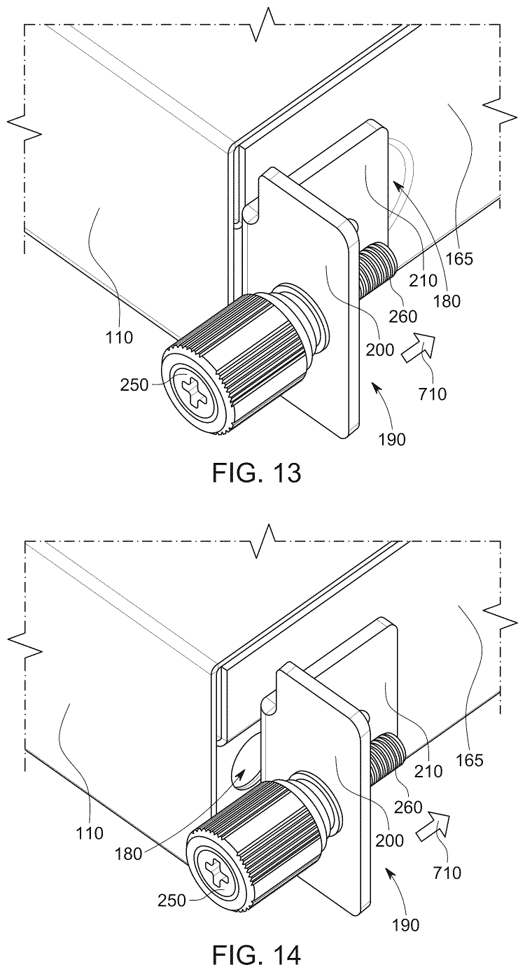

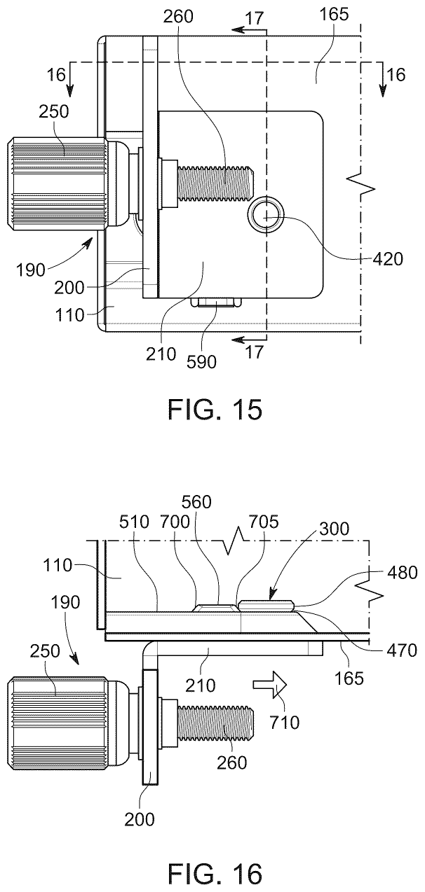

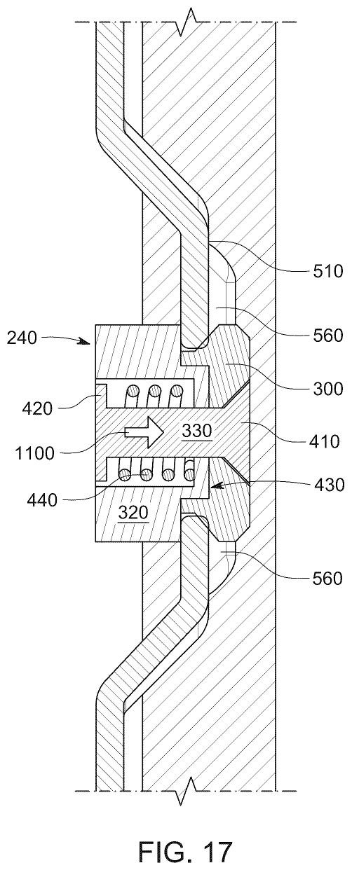

Referring to FIG. 13, the mounting accessory 190 is shown in an external perspective view in the same position relative to the server chassis 110, as shown in FIGS. 9-11. Continuing to apply force to the mounting accessory 190 in the direction of arrow 710 from the position shown in FIG. 13, forces the cap component 300 down the third ramped surfaces 705. The cap component 300 is pulled toward the hollow body 320 by the bias of the spring 440 until the mounting accessory 190 reaches the position relative to the server chassis 110, as shown in FIGS. 14 and 15. FIGS. 16 and 17 are additional views of the mounting accessory 190 in the position shown in FIGS. 14 and 15, and show additional geometric details of the interaction of the cap component 300 with the bridge elements 560.

FIG. 16 shows a top plan view of the mounting accessory 190 looking generally along the lines 16-16 of FIG. 15. This view shows the cap component 300 back in contact with the inside surface 510 of the server chassis 110. FIG. 17 shows a cross-sectional view of the lock component 240 looking generally along the lines 17-17 of FIG. 15. This view shows the cap component 300 in front of the bridge elements 560 and back in contact with the inside surface 510 of the server chassis 110. In this configuration, the cap component 300 is held against the inside surface 510 by the bias of the spring 440 applied through the first flange 410 of the pin 330. The spring 440 in this configuration has returned to the original position or nearly to the original position of the spring 440, shown in FIG. 4.

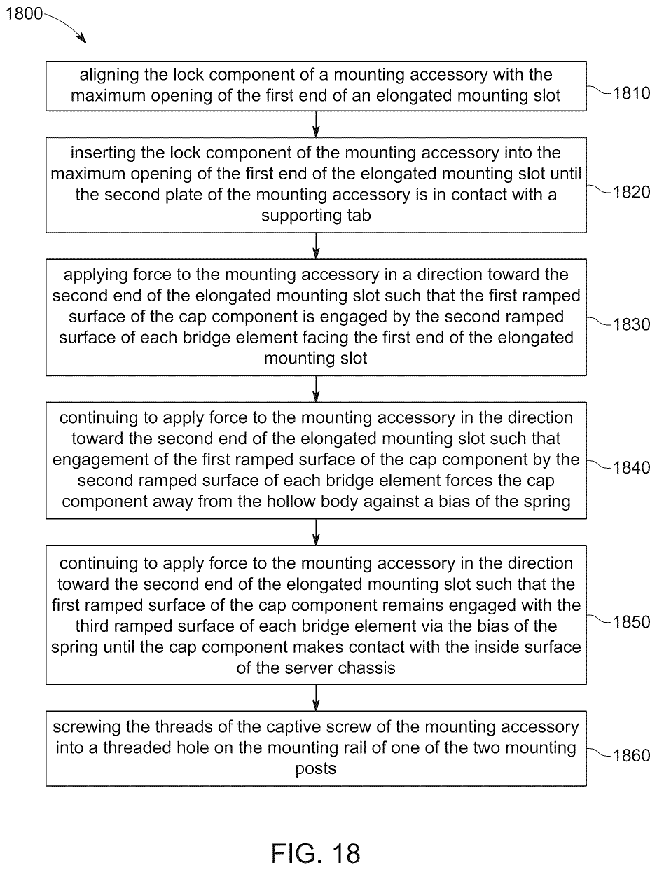

The components and assembly of an embodiment of the server mounting system 100 have been described above. Referring to FIG. 18, a method 1800 of securing a server chassis 110 within a server cabinet 130 is summarized for each of the first and second side panels 165, 170 of the server chassis 110. The method 1800 starts at step 1810 with aligning the lock component 240 of a mounting accessory 190, as shown in FIG. 5, with the maximum opening 530 of the first end 520 of an elongated mounting slot 180.

The method 1800 continues at step 1820 with inserting the lock component 240 of the mounting accessory 190 into the maximum opening 530 of the first end 520 of elongated mounting slot 180, as shown in FIGS. 6 and 7, until the second plate 210 of the mounting accessory 190 is in contact with a supporting tab 590. The method 1800 continues at step 1830 with applying force to the mounting accessory 190 in the direction of arrow 710 toward the second end 540 of the elongated mounting slot 180, as shown in FIG. 7. Such application of force causes the first ramped surface 470 of the cap component 300 to be engaged by the second ramped surface 700 of each bridge element 560 facing the first end 520 of the elongated mounting slot 180.

Still referring to FIG. 18, the method 1800 continues at step 1840 with continuing to apply force to the mounting accessory 190 in the direction of arrow 710, as shown in FIG. 8. The continued application of force in the direction of arrow 710 causes the mounting accessory 190 to move to the position relative to the server chassis 110, as shown in FIGS. 9 and 10. As shown in FIGS. 11 and 12, in this configuration, the engagement of the first ramped surface 470 of the cap component 300 by the second ramped surface 700 of each bridge element 560 has forced the cap component 300 in the direction of arrow 1100 away from the hollow body 320 against a bias of the spring 440.

Still referring to FIG. 18, the method 1800 continues at step 1850 with continuing to apply force to the mounting accessory 190 in the direction of arrow 710, as shown in FIG. 13. The continued application of force in the direction of arrow 710 causes the mounting accessory 190 to move to the position relative to the server chassis 110, as shown in FIGS. 14 and 15. In so moving from the position shown in FIG. 13 to the position shown in FIGS. 14 and 15, the first ramped surface 470 of the cap component 300 remains engaged with the third ramped surface 705 of each bridge element 560 via the bias of the spring 440 against a bias of the spring 440 until the cap component 300 makes contact with the inside surface 510 of the server chassis 110. In this configuration, the cap component 300 is trapped behind the maximum opening 550 of the second end 540 of the elongated mounting slot 180.

Still referring to FIG. 18, the method 1800 continues at step 1860 with screwing the threads 260 of the captive screw 250 of the mounting accessory 190 into a threaded mounting hole 160 on the mounting rail 150 of one of the two mounting posts 120.

Referring to FIG. 19, the server chassis 110 is shown mounted in the server cabinet 130 via a different elongated mounting slot 180 and at a different depth than is the server chassis 110 shown in FIG. 1.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A server mounting system, comprising:
a mounting post having a mounting rail, the mounting rail including a plurality of mounting holes;
a server chassis having a side panel with an outside surface and an inside surface, the side panel including at least one elongated mounting slot disposed through the side panel between the outside surface and the inside surface; and
a mounting accessory defined in part by a plate and configured to couple the server chassis to the mounting post, the mounting accessory including
a lock component extending from the mounting accessory and configured to securely couple with the at least one elongated mounting slot; and
a captive screw disposed through and free to rotate relative to the plate, the captive screw being configured to threadably mate with one of the plurality of mounting holes.

2. The server mounting system of claim 1, wherein the plate is a first plate, the mounting accessory further being defined by a second plate, the second plate extending in a first direction transversely away from an edge of the first plate, the lock component extending from the second plate in a second direction away from the first plate, the captive screw being oriented such that threads of the captive screw extend in the first direction.

3. The server mounting system of claim 2, wherein the lock component includes a cap component having a cap diameter.

4. The server mounting system of claim 3, wherein the lock component further includes a hollow body affixed to the second plate, a spring, and a pin disposed through the hollow body, the pin including a first flange at a first end and a second flange at a second end, wherein the cap component is disposed around the pin and captured between the first flange and an outside of the hollow body, the spring being captured between the second flange and an inside of the hollow body and biasing the first flange toward the hollow body.

5. The server mounting system of claim 4, wherein the at least one elongated mounting slot has a first end having a maximum opening that is larger than the cap diameter and a second end having a maximum opening that is smaller than the cap diameter.

6. The server mounting system of claim 5, wherein the at least one elongated mounting slot is at least partly bounded by a bridge element extending away from the inside surface of the side panel along each long edge of the at least one elongated mounting slot between the first end and the second end, each bridge element having a first ramped surface facing the first end of the at least one elongated mounting slot and a second ramped surface facing the second end of the at least one elongated mounting slot.

7. The server mounting system of claim 6, wherein a side of the cap component facing the hollow body includes a ramped surface extending radially away from a circumferential edge of the cap component, the ramped surface configured to be complementary to the first and second ramped surfaces of the bridge element.

8. The server mounting system of claim 1, further comprising a supporting tab extending away from the outside surface of the side panel and spaced from a long edge of the at least one elongated mounting slot.

9. A server mounting system, comprising:
a mounting post having a mounting rail, the mounting rail including a plurality of mounting holes;
a server chassis having a side panel with an outside surface and an inside surface, the side panel including at least two elongated mounting slots disposed through the side panel between the outside surface and the inside surface of the side panel; and
a mounting accessory configured to couple the server chassis to the mounting post, the mounting accessory including:
a first plate and a second plate, the second plate extending in a first direction transversely away from an edge of the first plate;
a lock component extending from the second plate in a second direction away from the first plate, the lock component configured to securely couple with one of the at least two elongated mounting slots; and
a captive screw disposed through and free to rotate relative to the first plate and oriented such that threads of the captive screw extend in the first direction, the captive screw being configured to threadably mate with one of the plurality of mounting holes.

10. The server mounting system of claim 9, wherein the lock component includes a cap component having a cap diameter, a hollow body affixed to the second plate, a spring, and a pin disposed through the hollow body, the pin including a first flange at a first end and a second flange at a second end, and wherein the cap component is disposed around the pin and captured between the first flange and an outside of the hollow body, the spring being captured between the second flange and an inside of the hollow body and biasing the first flange toward the hollow body.

11. The server mounting system of claim 10, wherein each of the at least two elongated mounting slots has a first end having a maximum opening that is larger than the cap diameter and a second end having a maximum opening that is smaller than the cap diameter.

12. The server mounting system of claim 11, wherein each of the at least two elongated mounting slots is at least partly bounded by a bridge element extending away from the inside surface of the side panel along each long edge of each of the at least two elongated mounting slots between the first end and the second end, each bridge element having a first ramped surface facing the first end of one of the at least two elongated mounting slots and a second ramped surface facing the second end of the one of the at least two elongated mounting slots.

13. The server mounting system of claim 12, wherein a side of the cap component facing the hollow body includes a ramped surface extending radially away from a circumferential edge of the cap component, the ramped surface configured to be complementary to the first and second ramped surfaces of the bridge element.

14. A server mounting system, comprising:
a server chassis having two opposite side panels each side panel including an outside surface and an inside surface, and each side panel including at least two elongated mounting slots disposed through the side panel between the outside surface and the inside surface of the side panel;
two mounting accessories, each mounting accessory configured to couple one of the two opposite side panels to a mounting post, each mounting accessory defined in part by a plate, and including:
a lock component extending from the mounting accessory and configured to securely couple with one of the at least two elongated mounting slots; and
a captive screw disposed through and free to rotate relative to the plate, the captive screw being configured to mate with a threaded hole on a mounting rail of the mounting post.

15. The server mounting system of claim 14, wherein the plate is a first plate, the mounting accessory further being defined by a second plate, the second plate extending in a first direction transversely away from an edge of the first plate, the lock component extending from the second plate in a second direction away from the first plate, and the captive screw disposed through the first plate and oriented such that threads of the captive screw extend in the first direction.

16. The server mounting system of claim 15, wherein the lock component includes a cap component having a cap diameter, a hollow body affixed to the second plate, a spring, and a pin disposed through the hollow body, the pin including a first flange at a first end and a second flange at a second end, wherein the cap component is disposed around the pin and captured between the first flange and an outside of the hollow body, the spring being captured between the second flange and an inside of the hollow body and biasing the first flange toward the hollow body.

17. The server mounting system of claim 16, wherein each of the at least two elongated mounting slots has a first end having a maximum opening that is larger than the cap diameter and a second end having a maximum opening that is smaller than the cap diameter.

18. The server mounting system of claim 17, wherein each of the at least two elongated mounting slots is at least partly bounded by a bridge element extending away from the inside surface of the side panel along each long edge of each of the at least two elongated mounting slots between the first end and the second end, each bridge element having a first ramped surface facing the first end of one of the at least two elongated mounting slots and a second ramped surface facing the second end of the one of the at least two elongated mounting slots.

19. The server mounting system of claim 18, further comprising a plurality of supporting tabs, each supporting tab extending away from the outside surface of one of the two opposite side panels and spaced from a long edge of one of the at least two elongated mounting slots, and wherein a side of the cap component facing the hollow body includes a ramped surface extending radially away from a circumferential edge of the cap component, the ramped surface configured to be complementary to the first and second ramped surfaces of the bridge element.

20. A method of securing a server within a server cabinet having two mounting posts using the server mounting system of claim 19, the method including:
for each of the two opposite side panels of the server chassis;
aligning the lock component of one of the two mounting accessories with the maximum opening of the first end of one of the at least two elongated mounting slots;
inserting the lock component of the one of the two mounting accessories into the first end of the one of the at least two elongated mounting slots until the second plate of the one of the two mounting accessories is in contact with a supporting tab of the plurality of supporting tabs;
applying force to the one of the two mounting accessories in a direction toward the second end of the one of the at least two elongated mounting slots such that the ramped surface of the cap component is engaged by the first ramped surface of each bridge element;
continuing to apply force to the one of the two mounting accessories in the direction toward the second end of the one of the at least two elongated mounting slots such that engagement of the ramped surface of the cap component by the first ramped surface of each bridge element forces the cap component away from the hollow body against a bias of the spring;
continuing to apply force to the one of the two mounting accessories in the direction toward the second end of the one of the at least two elongated mounting slots such that the bias of the spring maintains engagement of the ramped surface of the cap component with the second ramped surface of each bridge element until the cap component makes contact with the inside surface of the server chassis; and
screwing the threads of the captive screw of the one of the two mounting accessories securely into the threaded hole on the mounting rail of one of the two mounting posts.
